(19) United States
(12) Patent Application Publication
(10) Pub. No.: US 2006/0134877 A1
(43) Pub. Date: Jun. 22, 2006

(54) Method for fabricating a buried conductive connection to a trench capacitor and a memory cell with such a connection

(75) Inventors: Bernd Goebel, Taufkirchen (DE); Dietmar Temmler, Dresden (DE); Arnd Scholz, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, München (DE)

(21) Appl. No.: 11/285,378

(22) Filed: Nov. 23, 2005

(30) Foreign Application Priority Data
Nov. 26, 2004 (DE) 10 2004 057 181.3

(51) Int. Cl. H01L 29/94; H01L 21/20; H01L 27/108; H01L 29/76; H01L 31/119

(52) U.S. Cl. 438/389; 257/301

(57) ABSTRACT

A buried conductive connection to a trench capacitor is formed in such a way that a contact area is provided between a conductive material layer which is arranged in the trench of the trench capacitor and contains a dopant and a semiconductor substrate between a first and a second predetermined trench depth, then dopant is outdiffused into the semiconductor substrate via the contact area by means of heating, in order to form the buried conductive connection in the semiconductor substrate, and afterward the conductive material layer containing the dopant is etched back into the trench as far as a third trench depth lying between the first and second predetermined trench depths, and the trench is covered with an insulation layer.

### CLAIM FOR PRIORITY

This application claims the benefit of priority to German Application No. 10 2004 057 181.3, filed Nov. 26, 2004.

### TECHNICAL FIELD OF THE INVENTION

The present invention relates to a method for fabricating a buried conductive connection to a trench capacitor and a memory cell with such a connection.

### BACKGROUND OF THE INVENTION

In semiconductor memories, in particular in dynamic random access memories (DRAMs), use is predominantly made of 1-transistor memory cells composed of a selection transistor and a storage capacitor, the information being stored in the storage capacitor in the form of electrical charges.

In this case, the semiconductor memory generally comprises a matrix of such memory cells which are connected up in the form of rows and columns. The row connections are usually referred to as word lines and the column connections as bit lines. In this case, the selection transistor and the storage capacitor of the memory cell are connected to one another in such a way that when the selection transistor is driven via a word line, the charge of the storage capacitor can be read in and out via a bit line.

The main emphasis in the technological development of memory cells is the storage capacitor. In order to ensure a sufficient storage capacitance with the memory cell area continuously decreasing from technology generation to technology generation, storage capacitors that utilize the third dimension have been developed. Such a three-dimensional storage capacitor is the trench capacitor, also referred to as deep trench capacitor, in which, in a semiconductor substrate, a first outer capacitor electrode is formed around a lower trench region, said electrode being isolated from a second inner capacitor electrode in the trench by a dielectric layer.

The selection transistor of the memory cell is usually arranged as a planar field effect transistor alongside the trench capacitor and has two electrode regions in the semiconductor substrate, between which a channel region is formed, which is isolated from a gate electrode arranged above by means of an insulator layer. In this case, the inner capacitor electrode of the trench capacitor is connected to the adjacent electrode region of the selection transistor via a buried conductive connection, a so-called buried strap contact.

As the feature sizes of the memory cells are increasingly shrunk, ever higher requirements are made of the geometrical ratios of the cell structure, of the technological process implementation, and of the electrical performance of the storage capacitor and of the selection transistor. This also applies in particular to the design of the buried conductive connection for linking the inner capacitor electrode of the trench capacitor to one electrode region of the selection transistor. The buried conductive connection is generally produced by outdiffusion of dopant atoms from the inner capacitor electrode into the adjoining semiconductor substrate.

In this case, the procedure is generally such that an insulation collar, which isolates the inner capacitor electrode from the surrounding semiconductor substrate, is removed in the region provided for forming the buried connection and the trench is subsequently filled again with a material containing a dopant, preferably the material of the inner capacitor electrode. By means of a subsequent heating process, which may also be effected in the context of forming the further components of the memory cell, dopant is then outdiffused isotropically from the filling material in the trench into the adjoining semiconductor substrate.

The advancing miniaturization of the memory cell means, however, that the interface between the buried conductive connection and the inner capacitor electrode moves ever nearer to the channel region of the selection transistor, thus giving rise to the risk of short circuits. Furthermore, the shrinking of feature sizes and the shifting of the inner capacitor electrode of the trench capacitor to the bit line contact of the selection transistor shorten the effective transistor length, so that high electric fields arise during the switching operation of the transistor in particular also in the region of the interface between the inner capacitor electrode and the buried conductive connection, said high electric fields leading to amplified leakage currents.

The increasing miniaturization additionally provides for higher requirements made of the overlay accuracy of the individual process steps for forming the components of the memory cell. In this case, the buried conductive connection for linking the inner capacitor electrode to the adjacent electrode region of the selection transistor greatly restricts the process window for orienting the gate electrode of the selection transistor with respect to the trench capacitor, since the buried conductive connection extending as far as the semiconductor surface precisely prescribes the position of the connected electrode region of the selection transistor and so positional errors of the gate electrode can lead to very high electric fields during the switching of the selection transistor and thereby amplified leakage currents.

### SUMMARY OF THE INVENTION

It is an object of the present invention to provide a method for fabricating a buried conductive connection to a trench capacitor and a memory cell with such a connection by means of which the distance from the interface between the inner capacitor electrode and the buried conductive connection to a selection transistor can be established in a flexible manner.

According to the invention, the buried conductive connection to a trench capacitor is formed in such a way that a contact area is provided between a conductive material layer which is arranged in the trench of the trench capacitor and contains a dopant and a semiconductor substrate between a first and a second predetermined trench depth, then dopant is outdiffused from the conductive material layer containing the dopant into that region of the semiconductor substrate which adjoins the contact area, in order to form the buried conductive connection in the semiconductor substrate, afterward the conductive material layer containing the dopant is etched back into the trench as far as a third trench depth lying between the first and second trench depths, and, finally, the trench is covered with an insulator layer.

This procedure according to the invention affords the possibility of setting the position of the interface between the buried conductive connection and the inner capacitor electrode independently of the perpendicular extent of the buried conductive connection in the semiconductor substrate. In this case, the interface can be pulled back in particular with respect to the semiconductor surface, thus resulting in an increased distance between the interface and hence the inner capacitor electrode of the trench capacitor and a channel region of an adjacent selection transistor. This is advantageous particularly in the case of recent memory cell layouts in which the gate electrode, in contrast to conventional planar selection transistors, extends into the semiconductor substrate. Furthermore, by pulling back the interface between the inner capacitor electrode and the conductive connection into the semiconductor substrate, it is possible to increase the effective transistor length and thus to reduce the leakage currents in the selection transistor which are produced in the case of shortened transistor lengths on account of the high electric fields arising during the switching operation.

### BRIEF DESCRIPTION OF THE DRAWINGS

The invention is explained in more detail with reference to the accompanying drawings, in which:

FIG. 1 shows a circuit diagram of a dynamic memory cell in a DRAM; and

FIGS. 2 to 9 show an embodiment of the method according to the invention for fabricating a memory cell having a buried conductive connection.

### DETAILED DESCRIPTION OF THE INVENTION

The invention is explained on the basis of a process sequence for forming a dynamic memory cell in a DRAM memory. In this case, the individual structures of the dynamic memory cell are preferably formed with the aid of the silicon planar technique, which comprises a sequence of individual processes which in each case act over the whole area of the surface of a silicon substrate, a local alteration of the silicon substrate being carried out in a targeted manner by means of suitable masking layers. During DRAM memory fabrication, a multiplicity of dynamic memory cells in matrix form are formed simultaneously in this case. However, the invention is described below only with regard to the formation of an individual dynamic memory cell.

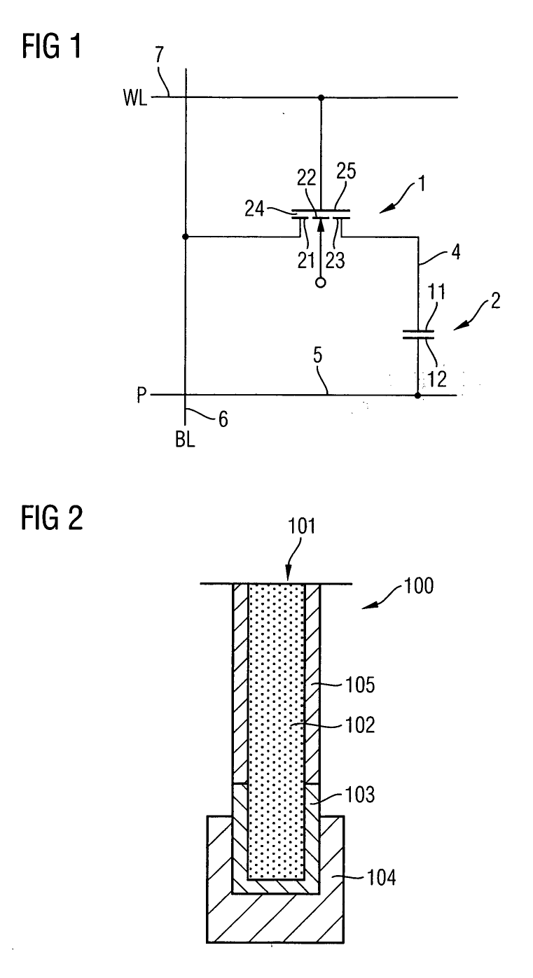

A circuit diagram of a 1-transistor memory cell that is preferably used in DRAM memories is shown in FIG. 1. This 1-transistor memory cell comprises a storage capacitor 1 and a selection transistor 2. In this case, the selection transistor 2 is preferably formed as a field effect transistor and has a first source/drain electrode 21 and a second source/drain electrode 23, between which a channel region 2 is formed.

Arranged above the channel region 22 are a gate insulator layer 24 and a gate electrode 25, which act like a plate capacitor that can influence the charge density in the channel region 22, in order to form or to block a current-conducting channel between the first source/drain electrode 21 and the second source/drain electrode 23.

The second source/drain electrode 23 of the selection transistor 2 is connected to a first capacitor electrode 11 of the storage capacitor 1 via a connecting line to the buried conductive connection. A second capacitor electrode 12 of the storage capacitor 1 is in turn connected to a capacitor plate 5, which is preferably common to all the storage capacitors of the DRAM memory cell arrangement. The first source/drain electrode 21 of the selection transistor 2 is furthermore connected to a bit line 6 in order that the information items stored in the form of charges in the storage capacitor 1 can be read in and out. In this case, a read-in and read-out operation is controlled via a word line 7, which is simultaneously the gate electrode 25 of the selection transistor 2, in order to produce a current-conducting channel in the channel region 22 between the first source/drain electrode 21 and the second source/drain electrode 23 of the selection transistor by application of a voltage.

In dynamic memory cells, trench capacitors are preferably used as storage capacitors since a substantial reduction of the memory cell area can be achieved by means of the three-dimensional structure. The selection transistor is generally formed as a planar field effect transistor in a manner laterally adjoining the trench capacitor. On account of the advancing miniaturization, however, such conventional planar selection transistors are increasingly being formed in stepped fashion with a gate electrode extending into the semiconductor substrate, in order to increase the effective channel length.

One difficulty in the context of the advancing reduction of the memory cell area is, in particular, the very close proximity of trench capacitor and selection transistor, which can adversely influence primarily the functionality of the selection transistor. In particular, there is the risk in this case that a short circuit can occur as a result of the shifting of the interface between the capacitor electrode and the buried conductive connection, which connects the inner capacitor electrode to one source/drain electrode of the selection transistor, to the channel region. Furthermore, this shifting shortens the effective transistor length, which has a disadvantageous influence on the performance of the memory cell. Thus, amplified leakage currents can occur in the switched-off state of the selection transistor, thereby significantly shortening the retention time of the charge in the trench capacitor. Moreover, the transistor switching behavior is substantially impaired.

The method according to the invention affords the possibility of defining the position of the interface between the capacitor electrode and the buried conductive connection for electrically linking the capacitor electrode to the adjacent source/drain electrode of the selection transistor independently of the vertical length of the buried conductive connection, and thus displacing said interface away from the semiconductor surface and the channel region of the selection transistor. By this means it is possible to increase the effective transistor length and thus to reduce the electric fields during the switching of the selection transistor and the leakage currents resulting therefrom.

Since the buried conductive connection according to the invention does not extend as far as the surface of the semiconductor substrate, the process window for the positional accuracy of the gate electrode of the selection transistor with respect to the trench capacitor is additionally enlarged since the source/drain electrode of the selection transistor that is connected to the inner capacitor electrode of the trench capacitor via the buried conductive connection, for compensating for positional inaccuracies, can be displaced in the direction of the trench capacitor.

The possibility of defining the position of the interface between the capacitor electrode of the trench capacitor and the buried conductive connection independently of the vertical extent of the buried conductive connection is achieved according to the invention by virtue of the fact that the fabrication of the buried conductive connection involves fabricating a contact area in the upper trench region of the trench capacitor between a conductive material layer containing a dopant and the semiconductor substrate. In this case, the contact area lies between a first and a second trench depth, which essentially defines the vertical length of the buried conductive connection. Via this contact area, dopant is then outdiffused from the conductive material layer containing the dopant into the adjoining semiconductor substrate by means of a heating step, in order to form the buried conductive connection.

The conductive material layer containing the dopant is subsequently etched back into the trench as far as a third trench depth lying between the first and second trench depths, in order to define the position of the interface between the inner capacitor electrode of the storage capacitor and the buried conductive connection, independently of the vertical length of the buried conductive connection produced beforehand by outdiffusion.

FIGS. 2 to 9 show a possible process sequence for forming a memory cell having a buried conductive connection according to the invention using the silicon planar technique, the schematic cross sections illustrated showing a detail from a silicon wafer 100 after the last individual process respectively described. In this case, only the process steps for forming the memory cell which are essential to the invention are discussed below. Unless described differently, the structures are otherwise formed in the context of customary DRAM process technology.

FIG. 2 shows a detail from the silicon wafer 100 in which a trench capacitor is embodied. The silicon wafer 100 is preferably a monocrystalline silicon substrate, which is preferably weakly p-doped (p⁻-doped), e.g. with boron. A trench 101 embodied in the silicon substrate 100 is preferably filled with polysilicon 102, which is highly n-doped (n⁺-doped), e.g. with arsenic or phosphorous. This polysilicon filling 102 forms the inner capacitor electrode of the trench capacitor.

The polysilicon filling 102 is enclosed by a storage dielectric layer 103 in the lower trench region. In this case, said storage dielectric layer 103 may comprise a stack of dielectric layers, e.g. made of oxide-nitride-oxide (ONO), which are distinguished by a high dielectric constant. An n⁺-doped layer 104, doped for example with arsenic or phosphorous, is formed in the lower trench region around the polysilicon filling 102 enclosed by the storage dielectric layer 103. Said n⁺-doped layer 104 serves as the outer capacitor electrode of the trench capacitor. In the upper trench region, the polysilicon filling 102 is separated from the silicon substrate 100 by an insulator layer 105, preferably an SiO₂ layer, in the form of an insulator collar.

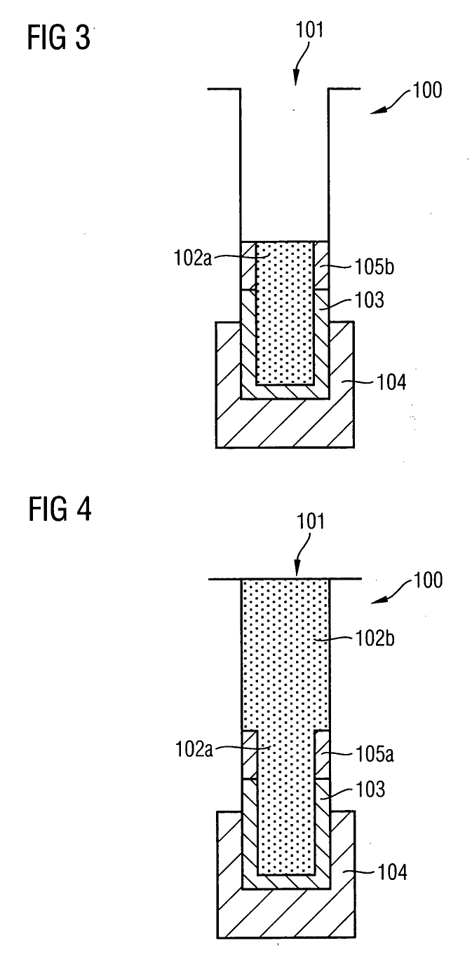

In order to form a connection of the polysilicon filling 102 in the trench capacitor to a source/drain electrode of a selection transistor of the memory cell, a first step involves carrying out a polysilicon etching down to a first trench depth, which essentially represents the lower boundary of the interface of the buried conductive connection. In this case, by way of example, an etching mask that is used is a silicon nitride mask (not shown) which frees the opening of the trench 101. After the polysilicon filling 102a has been etched back into the trench, the uncovered region of the insulator collar is then removed by means of a further etching. FIG. 3 shows a cross section through the silicon wafer 100 with the remaining polysilicon filling 102a and the remaining insulator collar 105b after the two etching steps described above.

In a next process step, the doping material used for forming the buried conductive connection in the silicon substrate 100 is then introduced into the trench 101. In this case, the filling material 102b is preferably n⁺-doped polysilicon again, thus giving rise to a homogeneous filling with the etched-back polysilicon block 102a. A cross section after the second filling of the trench with polysilicon 102 is illustrated in FIG. 4.

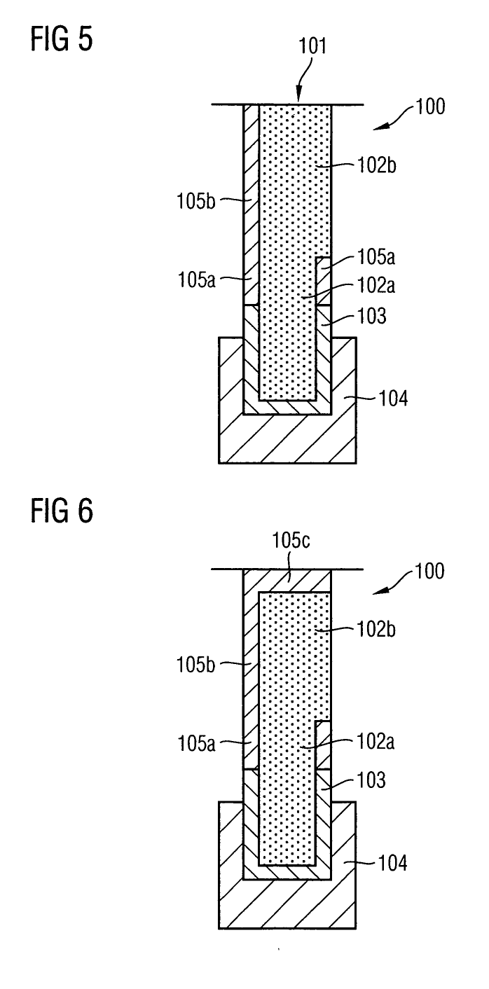

The position of the buried conductive connection is defined in a further process sequence. In the embodiment shown, the buried conductive connection is formed as a so-called single-sided buried strap contact on only one side of the trench. In order to define the outdiffusion region, a lateral etching process is performed in the second polysilicon filling 102b once again preferably with the aid of an SiO₂ mask (not shown). For this purpose, the polysilicon filling is again etched back as far as the insulator collar 105a, but only on that side of the trench on which the buried conductive connection is not intended to be formed subsequently. On the uncovered trench wall, a second insulator layer 105b, preferably once again an SiO₂ layer, is then applied and the trench is subsequently filled with the n⁺-doped polysilicon 102b again. A cross section through the silicon wafer 100 after this third filling process, during which an essentially homogeneous n⁺-doped polysilicon filling is fabricated in the trench 101, is illustrated in cross section in FIG. 5.

The upper boundary of the buried conductive connection is defined in a next process step. This is done by etching back the highly n⁺-doped polysilicon filling 102 in the trench to a second trench depth, which defines the distance between the buried conductive connection and the silicon surface. The trench 101 is then preferably filled with a further insulator layer 105c, once again preferably with an SiO₂ layer. However, the insulator layer 105c may alternatively be dispensed with. A cross section through the silicon wafer 100 after the last-mentioned process step is illustrated in FIG. 6.

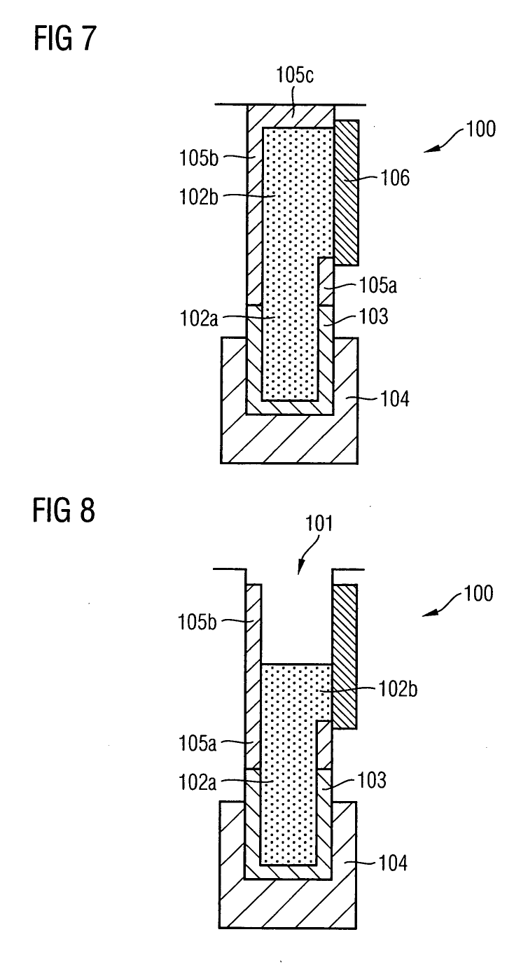

Afterward, by means of a baking step, the n-type dopant is then diffused from the polysilicon filling 102 in the trench 100 at the open contact area to the silicon substrate 101 into the monocrystalline silicon substrate in order to fabricate the buried conductive connection 106. In this case, the outdiffusion is essentially isotropic, resulting in an essentially uniform n-type doping adjoining the contact area to the polysilicon filling 102 in the trench 101 in the silicon substrate 100. Depending on the n-type dopant of the polysilicon filling, heating is carried out to a temperature of 900 to 1100° C. for a few seconds. In this case, the outdiffusion process is designed such that the buried conductive connection is at a distance from the silicon surface, as shown in the cross section in FIG. 7. In this case, the vertical length of the buried conductive connection 106 corresponds to the length of the contact window to the polysilicon filling 102 in the trench 101, increased by the diffusion length of the dopant in the silicon substrate during the heating process.

In order to define the position of the contact area between the n⁺-doped polysilicon filling 102 forming the inner capacitor electrode and the buried conductive connection 106 formed by outdiffusion, in a two-stage etching process, firstly the SiO₂ covering layer 105c above the trench is removed and then the polysilicon filling 102 in the trench 101 is etched back to the desired third trench depth, that is to say the desired distance between the upper boundary of the contact area and the silicon wafer surface. In this case, said third trench depth lies between the first and second trench depths and can be set independently of the lateral extent of the buried conductive connection 106. A cross section through the silicon wafer 101 after the etching-back process of the polysilicon filling 102 for the purpose of setting the position of the contact area is illustrated in FIG. 8.

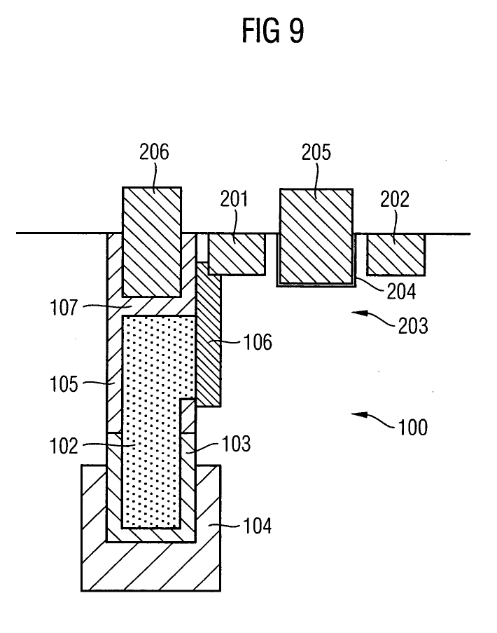

The further components of the memory cell are then formed in a further process sequence known from the standard DRAM process. FIG. 9 shows a cross section through the completed memory cell. The selection transistor, which has two n⁺-doped diffusion regions 201, 202 for forming the two source/drain electrodes, is formed essentially in planar fashion in a manner adjoining the trench capacitor. In this case, the n⁺-doped diffusion region 201 adjoining the trench capacitor is formed in a manner overlapping the buried conductive connection 106 in order to connect the selection transistor to the polysilicon filling 102 of the trench capacitor. A channel region 203 is formed between the two n⁺-doped diffusion regions 201, 202, said channel region being separated from a word line 205 of the selection transistor—which word line serves as gate electrode—by a gate oxide layer 204. In this case, the word line 205 extends between the two n⁺-doped diffusion regions 201, 202 into the silicon substrate, as a result of which the effective channel length is increased.

Parallel to the word line 205 of the selection transistor of the memory cell, a further word line 206 is formed directly above the polysilicon filling 102 of the trench capacitor forming the inner capacitor electrode, said further word line serving for driving an adjacent memory cell in the DRAM memory. This arrangement of the passive word line 106 in the trench of the trench capacitor makes it possible to save memory cell area. In this case, the passive word line 106 is enclosed by an insulator layer, preferably an SiO₂ layer 107, in order to insulate the passive word line from the inner capacitor electrode, the buried conductive connection and the adjacent source/drain electrode of the selection transistor.

The procedure according to the invention, which makes it possible to set the depth of the interface between the inner capacitor electrode and the buried conductive connection independently of the lateral extent of the buried connection, affords the possibility of displacing said interface in particular deeper into the silicon substrate and thus of increasing the effective transistor length of the adjacent selection transistor, thereby in turn reducing the electric fields during the switching operation of the selection transistor and thus reducing possible leakage currents. At the same time it is possible to pull back the interface between the inner capacitor electrode and the buried conductive connection relative to the channel region of the adjacent selection transistor in order thus to avoid short circuits. The formation of the buried conductive connection according to the invention furthermore ensures that said conductive connection is at a distance from the silicon substrate surface, thereby enlarging the process window for the orientation of the source/drain electrodes of the selection transistor with respect to the associated word line. Furthermore, as a result of pulling back the interface between the inner capacitor electrode and the buried conductive connection, it is possible to ensure sufficient insulation for isolating the passive word line arranged above the inner capacitor electrode.

What is claimed is:

1. A method for fabricating a buried conductive connection to a trench capacitor in a semiconductor substrate, having the steps of:
providing a trench capacitor in the semiconductor substrate having an inner capacitor electrode provided in a trench, the inner capacitor electrode in a lower trench region being isolated from an outer capacitor electrode which is formed around the lower trench region, by a dielectric intermediate layer, the inner capacitor electrode in an upper trench region being isolated from the semiconductor substrate essentially by an insulator layer on the trench sidewall, and the inner capacitor electrode in the upper trench region having a conductive material layer containing a dopant, which material layer has a contact area with the semiconductor substrate between a first and a second predetermined trench depth,
outdiffusing dopant from the conductive material layer containing the dopant into the semiconductor substrate in the region of the contact area, in order to form a buried conductive connection in the semiconductor substrate,
etching back the conductive material layer containing the dopant into the trench as far as a third trench depth lying between the first and second predetermined trench depths, and
covering the trench with an insulator layer.

2. A method for fabricating a memory cell in a semiconductor substrate, having
a trench capacitor having an inner capacitor electrode provided in a trench, the inner capacitor electrode in a lower trench region being isolated from an outer capacitor electrode which is formed around the lower trench region, by a dielectric intermediate layer, the inner capacitor electrode in an upper trench region being isolated from the semiconductor substrate essentially by an insulator layer on the trench sidewall, and the inner capacitor electrode in the upper trench region having a conductive material layer containing a dopant, which material layer has a contact area with the semiconductor substrate between a first and a second predetermined trench depth,
and a selection transistor having a first electrode region adjoining the trench capacitor, a channel region isolated from a gate electrode by an insulator layer, and a second electrode region,
the first electrode region of the selection transistor being connected to the inner capacitor electrode of the trench capacitor via a buried connection, which is formed by outdiffusing dopant from the conductive material layer containing the dopant into the semiconductor substrate in the region of the contact area, in order to form a buried conductive connection in the semiconductor substrate, by etching back the conductive material layer containing the dopant into the trench as far as a third trench depth lying between the first and second predetermined trench depths, and by covering the trench with an insulator layer.

3. A method for fabricating a memory cell in a semiconductor substrate, having the steps of:
forming a trench capacitor in the semiconductor substrate having an inner capacitor electrode provided in a trench, the inner capacitor electrode in a lower trench region being isolated from an outer capacitor electrode which is formed around the lower trench region, by a dielectric intermediate layer, the inner capacitor electrode in an upper trench region being isolated from the semiconductor substrate essentially by an insulator layer on the trench wall, and the inner capacitor electrode in the upper trench region having a conductive material layer containing a dopant, which material layer has a contact window with the semiconductor substrate between a first and a second predetermined trench depth,
forming a buried conductive connection in the semiconductor substrate by indiffusing dopant from the conductive material layer containing the dopant into the semiconductor substrate via the contact window,
etching back the conductive material layer containing the dopant into the trench as far as a third trench depth lying between the first and second predetermined trench depths, in order to define a contact area between the inner capacitor electrode and the buried conductive connection formed by outdiffusion,
covering the trench with an insulator layer, and
forming a selection transistor having a first electrode region adjoining the trench capacitor, a channel region isolated from a gate electrode by an insulator layer, and a second electrode region, the first electrode region of the selection transistor being connected to the inner capacitor electrode of the trench capacitor via a buried conductive connection.

4. The method as claimed in claim 3, involving, for the purpose of forming the buried conductive connection,
carrying out an etching of a trench filling down to the first trench depth, which essentially represents the lower boundary of the interface of the buried conductive connection,
performing a removal of the uncovered region of the insulator layer on the trench wall by means of a further etching,
carrying out a filling of the trench with the conductive material containing the dopant,
performing a definition of the contact window by a process of laterally etching the conductive material layer containing the dopant as far as the insulator layer on the trench side on which the buried conductive connection is not intended to be formed subsequently, by applying a further insulator layer on the uncovered trench wall, by once again filling the trench with the conductive material containing the dopant, and by etching back the conductive material containing the dopant to the second trench depth, which essentially represents the upper boundary of the interface of the buried conductive connection,
carrying out an indiffusion of dopant from the conductive material containing the dopant into the semiconductor substrate via the contact window by means of a heating step, in order to fabricate the buried conductive connection, and
performing a definition of the contact area between the inner capacitor electrode and the buried conductive connection formed by outdiffusion, by etching back the conductive material containing the dopant to the third trench depth.

5. The method as claimed in claim 3, the trench filling and the conductive material containing the dopant being polysilicon.
